(19) United States
(12) Patent Application Publication
(10) Pub. No.: US 2006/0130967 A1
(43) Pub. Date: Jun. 22, 2006

(54) Wafer machining apparatus

(75) Inventors: Shinichi Fujisawa, Tokyo (JP); Takashi Ono, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/302,392

(22) Filed: Dec. 14, 2005

(30) Foreign Application Priority Data
Dec. 17, 2004 (JP) 2004-366040

(51) Int. Cl. H01L 21/306; C23F 1/00

(52) U.S. Cl. 156/345.1; 156/345.12

(57) ABSTRACT

The present invention provides a wafer machining apparatus which can separate streets with high efficiency, without deteriorating the quality of devices, in dividing a wafer into individual devices. The wafer machining apparatus comprises grinding means for grinding the back of the wafer; resist film coating means for passing a radiation from the back side to the face side of the wafer to recognize the streets, and coating a resist film onto regions other than street-corresponding regions; and plasma etching means for etching away the street-corresponding regions in a range from the back to the face of the wafer to divide the wafer into individual devices, and thus can perform a procedure ranging from grinding of the back of the wafer to the division of the wafer into the devices. In the resist film coating means, the wafer is imaged from the back side by an infrared imaging portion to recognize the streets formed on the face side, and a liquid resist is jetted from a resist jetting portion toward the regions other than the street-corresponding regions, whereby only the street-corresponding regions can be exposed.

### TECHNICAL FIELD

This invention relates to a wafer machining apparatus having the function of etching streets formed in a wafer to divide the wafer into individual devices.

### BACKGROUND ART

A wafer, on whose face a plurality of devices each composed of IC or LSI are formed by being partitioned by streets formed longitudinally and transversely, is divided into individual devices by separating the streets. The resulting devices are used in various types of electronic equipment.

Usually, the streets are cut by a cutting blade rotating at a high speed. If the thickness of the wafer is as small as 100 μm or less or 50 μm or less, the problem occurs that the devices are chipped by the crushing force of the cutting blade, and their deflective strength decreases, deteriorating their quality.

Thus, the following techniques have been proposed: A mask member is coated on the face of the wafer, and the cutting blade rotating at a high speed is cut into only portions of the mask member located above the streets to remove the mask member at these portions, thereby exposing the streets. Then, an etching agent is supplied to the face side of the wafer to etch only the street portions chemically. By so doing, the streets are separated to divide the wafer into individual devices (refs. JP-A 2001-127011 and JP-A 2003-257896). According to these techniques, the wafer needs not to be cut, and thus can prevent the deterioration of the quality of the devices.

### OBJECT AND SUMMARY OF THE INVENTION

However, to remove the mask member in regions corresponding to the streets with the use of the cutting blade, it is necessary to precisely align the cutting blade and individually cut the regions corresponding to the individual streets. Cutting the regions corresponding to all streets poses the problems of requiring a considerable time and giving low productivity. Particularly when the size of the device is small, the number of the streets is large, leading to lower productivity.

A plurality of apparatuses, such as a cutting apparatus and an etching apparatus, are needed, and the wafer needs to be transported between the apparatuses. This is another factor for lowering the productivity.

An object of the present invention is to be able to separate the streets with high efficiency, without deteriorating the quality of devices, in dividing the wafer into individual devices.

The present invention relates to a wafer machining apparatus for dividing a wafer, in which a plurality of devices are partitioned by streets formed on the face of the wafer, into individual devices, the wafer machining apparatus comprising a grinding means for grinding the back of the wafer having a protective member affixed to the face of the wafer to form the wafer in a predetermined thickness; a resist film coating means for passing a radiation through the wafer from the back side to the face side of the wafer to recognize the streets, and coating a resist film onto regions of the back of the wafer which are other than street-corresponding regions corresponding to the streets; and a plasma etching means for plasmatizing a fluorine-based stable gas, and supplying the plasmatized gas to the back side of the wafer to etch away the street-corresponding regions in a range from the back to the face of the wafer, thereby dividing the wafer into individual devices. The grinding means at least comprises a chuck table for sucking and holding the wafer, a grinding portion for grinding the back of the wafer held on the chuck table, and a cleaning portion for cleaning the ground wafer. The resist film coating means at least comprises a holding table for holding the wafer, an infrared imaging portion for imaging the wafer held on the holding table from the back side to recognize the streets formed on the face side, a resist jetting portion for jetting a liquid resist toward the regions of the back of the wafer which are other than the street-corresponding regions, and a heating portion for heating the jetted liquid resist to solidify the jetted liquid resist.

The cleaning portion is preferably equipped with an undercoating liquid jet nozzle for jetting an undercoating liquid for rendering a state of adhesion of the liquid resist to the back of the wafer satisfactory. Examples of the fluorine-based stable gas are SF₆, CF₄, C₂F₆, C₂F₄ and CHF₃. The plasma etching means can have the function of plasmatizing oxygen, and supplying the plasmatized oxygen to the back side of the wafer divided into the devices to ash and remove the resist film coated on the backs of the devices.

In the wafer machining apparatus according to the present invention, the grinding means, the resist film coating means, and the plasma etching means are provided. In the grinding means, the back of the wafer is ground to bring the wafer to a predetermined thickness, and the ground surface is cleaned. In the resist film coating means, the resist film is coated on the back of the wafer, except in the street-corresponding regions. In the plasma etching means, the exposed street-corresponding regions are etched, whereby the wafer can be divided into individual devices. Thus, a series of operations, ranging from the grinding of the back of the wafer to the division of the wafer into the devices, can be performed by the single apparatus to achieve high productivity. Since the wafer is not cut, moreover, the quality of the wafer is not deteriorated. In addition, in the plasma etching means, the liquid resist is jetted from the resist jetting portion at the regions other than the street-corresponding regions to coat a resist film. This obviates the need for the operation of coating a resist film on the entire back, and then cutting the resist film above the street-corresponding regions to remove such resist film, or exposing such resist film to light to remove it. Nor is an exposure device or the like necessary.

If the cleaning portion is equipped with the undercoating liquid jet nozzle for jetting an undercoating liquid for imparting a satisfactory state of adhesion of the liquid resist to the back of the wafer, the undercoating liquid is coated on the back of the wafer beforehand. By this measure, the state of adhesion of the resist film to the back of the wafer is rendered satisfactory when the resist film is coated by the resist film coating means.

If the plasma etching means has the function of plasmatizing oxygen, and supplying the plasmatized oxygen to the back side of the wafer divided into the devices to ash and remove the resist film coated on the back of the devices, this is efficient, because the procedure ending with the removal of the resist film can be performed by the single apparatus.

### BRIEF DESCRIPTION OF THE DRAWINGS

FIG. 1 is a perspective view showing an example of a wafer machining apparatus;

FIG. 2 is a schematic sectional view showing an example of the configuration of an etching portion constituting a plasma etching means;

FIG. 3 is a perspective view showing a wafer and a protective member;

FIG. 4 is a perspective view showing a state in which the protective member is affixed to the face of the wafer;

FIG. 5 is a schematic sectional view showing the manner of grinding the back of the wafer;

FIG. 6 is a perspective view showing an example of the configuration of a cleaning means; and

FIGS. 7(A) to 7(C) are schematic sectional views showing the procedure for dividing the wafer, 7(A) showing a state in which a resist layer (resist film) is coated on regions other than street-corresponding regions, 7(B) showing a state where the street-corresponding regions have been etched, and 7(C) showing a state where the resist film has been removed.

### PREFERRED EMBODIMENTS OF THE INVENTION

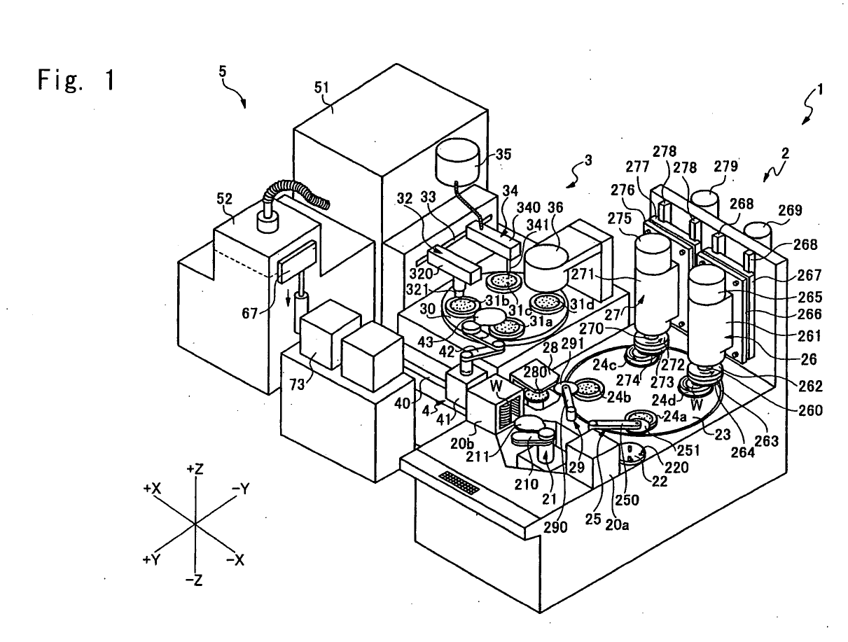

A wafer machining apparatus 1 shown in FIG. 1 shows an embodiment of the present invention, which comprises a grinding means 2 for grinding the back of a wafer to form the wafer in a predetermined thickness, a resist film coating means 3 for coating the back of the wafer with a resist film, and a plasma etching means 5 for dividing the wafer into individual devices by chemical etching.

The grinding means 2 is furnished with a first wafer cassette 20a and a second wafer cassette 20b for accommodating a plurality of wafers in a stacked state, and the wafers before grinding are accommodated into the first wafer cassette 20a and the second wafer cassette 20b.

A carry-out and carry-in means 21 having the function of carrying the wafer into and out of the necessary members is disposed between the first wafer cassette 20a and the second wafer cassette 20b. The carry-out and carry-in means 21 has a holding plate 211 provided at the front end of an arm portion 210 capable of bending and pivoting. The arm portion 210 with the holding plate 211 can be advanced into the interior of each of the first wafer cassette 20a and the second wafer cassette 20b.

A temporary placement table 22 having the function of aligning the wafer with a constant position is disposed at a position to which the holding plate 211 constituting the carry-out and carry-in means 21 is movable. A plurality of alignment members 220 movable toward or away from each other are disposed on the temporary placement table 22.

A turntable 23 is disposed at a position in proximity to the temporary placement table 22. The turntable 23 supports four chuck tables 24a, 24b, 24c and 24d such that these chuck tables can rotate on their axes and rotate along the circumference of the turntable. A first transport means 25 having an attraction plate 251 provided at the front end of an arm portion 250 capable of ascending, descending and pivoting is disposed in the neighborhood of the turntable 23 and the temporary placement table 22. The first transport means 25 can transport the wafer placed on the temporary placement table 22 to the chuck table located at a position close to the temporary placement table 22. In FIG. 1, the chuck table 24a is located at a position close to the first transport means 25.

A first grinding portion 26 and a second grinding portion 27 having the function of grinding the back of the wafer are disposed above the moving path of the chuck tables 24a, 24b, 24c, 24d.

The first grinding portion 26 has a spindle 260 rotatably supported by a housing 261, the spindle 260 having an axis in a vertical direction, and has a grinding wheel 263 fixed to a wheel mount 262 formed at the lower end of the spindle 260. For example, a grindstone 264 for rough grinding is secured to the lower surface of the grinding wheel 263, and a motor 265 is coupled to the upper end of the spindle 260. The housing 261 is fixed to an ascending and descending plate 267 via a fixing plate 266. The ascending and descending plate 267 slidably engages a pair of guide rails 268 disposed in the vertical direction, and ascends and descends upon driving of a motor 269. In accordance with the ascent and descent, the first grinding portion 26 ascends and descends.

The second grinding portion 27 has a spindle 270 rotatably supported by a housing 271, the spindle 270 having an axis in a vertical direction, and has a grinding wheel 273 fixed to a wheel mount 272 formed at the lower end of the spindle 270. For example, a grindstone 274 for finish grinding is secured to the lower surface of the grinding wheel 273, and a motor 275 is coupled to the upper end of the spindle 270. The housing 271 is fixed to an ascending and descending plate 277 via a fixing plate 276. The ascending and descending plate 277 slidably engages a pair of guide rails 278 disposed in the vertical direction, and ascends and descends upon driving of a motor 279. In accordance with the ascent and descent, the second grinding portion 27 ascends and descends.

A cleaning means 28 for holding and cleaning the ground wafer in a spinner table 280 is disposed in the neighborhood of the second wafer cassette 20b. A second transport means 29 having an attraction plate 291 provided at the front end of an arm portion 290 capable of ascending, descending and pivoting is disposed near the chuck table located at the closest position to the cleaning means 28. The second transport means 29 can transport the ground wafer from the chuck table, which is located at the closest position, to the spinner table 280. In FIG. 1, the chuck table 24b is located at a position close to the second transport means 29.

The resist film coating means 3 is furnished with a turntable 30. In the illustrated embodiment, the turntable 30 supports four holding tables 31a, 31b, 31c and 31d such that these holding tables can rotate on their axes and rotate along the circumference of the turntable.

An infrared imaging portion 32 is disposed above the moving path of the holding tables 31a, 31b, 31c, 31d moving according to the rotation of the turntable 30. The infrared imaging portion 32 is provided with a moving portion 320 movable in a Y-axis direction while being guided by a guide portion 33, and an infrared camera 321 movable in an X-axis direction with respect to the moving portion 320. An image acquired by the imaging of the infrared camera 321 is stored in a memory (not shown) provided inside the infrared imaging portion 32.

A resist jetting portion 34 is disposed parallel to the infrared imaging portion 32 above the moving path of the holding tables 31a, 31b, 31c, 31d. The resist jetting portion 34 has the function of jetting a liquid resist like an ink jet, and is provided with a moving portion 340 movable in the Y-axis direction while being guided by the guide portion 33, and a resist nozzle 341 movable in the X-axis direction with respect to the moving portion 340 and adapted to jet the liquid resist at the wafer held by any of the holding tables. The resist nozzle 341 is coupled to a liquid resist tank 35 storing the liquid resist.

A heating portion 36 is provided above the moving path of the holding tables 31a, 31b, 31c, 31d, and has the function of heating the liquid resist jetted at the wafer by the resist jetting portion 34.

A transport device 4 for transporting the wafer is disposed in the neighborhood of the resist film coating means 3. The transport device 4 is composed of a guide rail 40 extending in the X-axis direction, a moving portion 41 movable in the X-axis direction along the guide rail 40, an arm portion 42 capable of ascending and descending with respect to the moving portion 41 and capable of bending, and a holding plate 43 provided in a front end portion of the arm portion 42.

The plasma etching means 5 is furnished with a gas supply portion 51, and an etching portion 52. The gas supply portion 51 stores a fluorine-based stable gas which is a fluorine-containing stable gas, such as SF₆, CF₄, C₂F₆, C₂F₄ or CHF₃. The etching portion 52 accommodates a wafer W, and plasmatizes the fluorine-based stable gas supplied from the gas supply portion 51 to etch the wafer W.

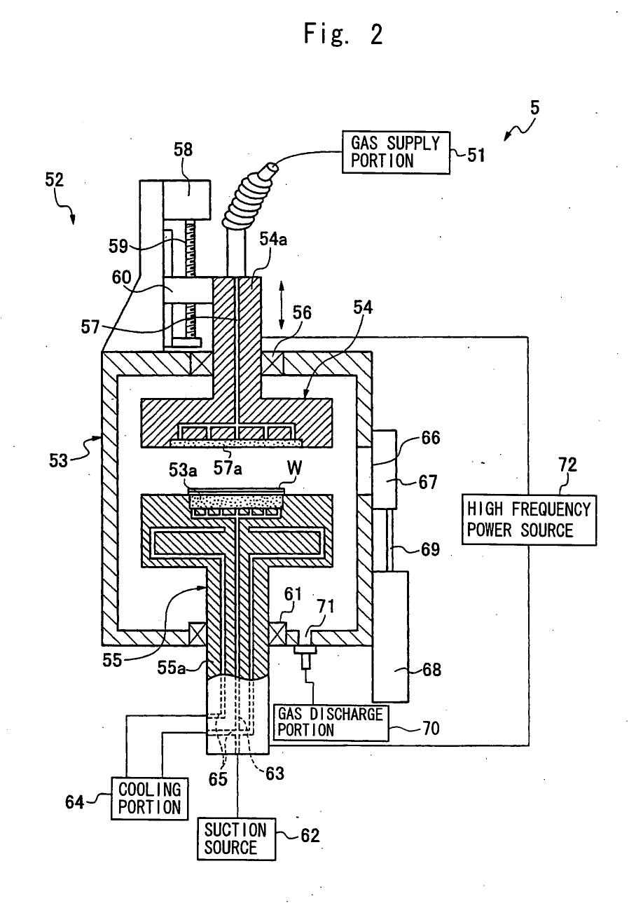

As shown in FIG. 2, the etching portion 52 has an etching gas spouting means 54 accommodated from an upper side of a chamber 53 where plasma etching is performed, and has a chuck table 55 accommodated from a lower side of the chamber 53 for holding a plate-shaped material to be etched.

The etching gas spouting means 54 has the function of supplying an etching gas to an exposed surface of the wafer W held on the chuck table 55, and has a shaft portion 54a inserted through an upper wall of the chamber 53 via a bearing 56 so as to be free to ascend and descend. Inside the etching gas spouting means 54, a gas flow-through hole 57 is formed which communicates with the gas supply portion 51 and also communicates with a spouting portion 57a formed of a porous member. A ball screw 59 is driven by a motor 58 to turn, whereupon an ascending and descending portion 60 having a nut screwed to the ball screw 59 ascends and descends. In accordance with this ascent and descent, the etching gas spouting means 54 also ascends and descends.

The chuck table 55 has a shaft portion 55a inserted through a bottom wall of the chamber 53 via a bearing 61 so as to be rotatable. Inside the chuck table 55, a suction passage 63 communicating with a suction source 62, and a cooling passage 65 communicating with a cooling portion 64 are formed, and the suction passage 63 communicates with a suction portion 53a located at an upper surface.

An opening portion 66, which serves as a carry-out and carry-in port for the plate-shaped material to be etched, is formed in a side portion of the chamber 53. A shutter 67, which opens and closes the opening portion 66 upon its ascent and descent, is disposed at the outside of the opening portion 66. The shutter 67 is caused to ascend and descend by a piston 69 which is driven by a cylinder 68 to ascend and descend.

An exhaust port 71 communicating with a gas discharge portion 70 is formed in a lower portion of the chamber 53, and a used gas can be discharged through the exhaust port 71. A high frequency power source 72 is connected to the etching gas spouting means 54 and the chuck table 55 to supply a high frequency voltage between the etching gas spouting means 54 and the chuck table 55, whereby an etching gas can be plasmatized.

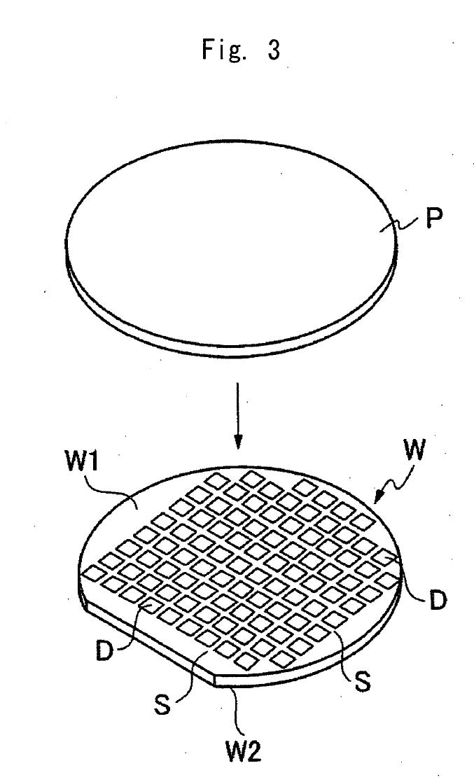

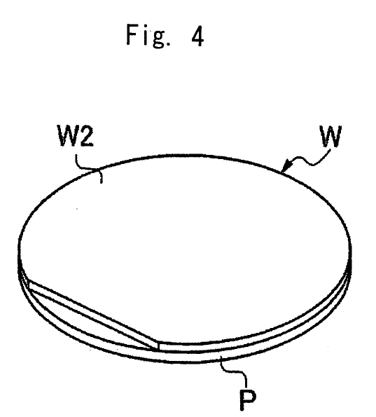

As shown in FIG. 3, a plurality of devices D are partitioned by streets S on the face W1 of the wafer W. A protective member P is affixed to the face W1 of the wafer W before being ground to be brought into a state as shown in FIG. 4. In this state, the wafer W is accommodated into the first wafer cassette 20a and the second wafer cassette 20b shown in FIG. 1.

With reference to FIG. 1, the wafer W having the protective member P affixed to the face W1 is carried out of the first wafer cassette 20a, with the back W2 of the wafer W being held by the holding plate 211 constituting the carry-out and carry-in means 21. Alternatively, if the first wafer cassette 20a is empty, such wafer W is carried out of the second wafer cassette 20b, and its protective member P is placed on the temporary placement table 22, with the back W2 of the wafer W being pointed upward and exposed. The wafer W is aligned with a constant position by the alignment members 220.

After alignment of the wafer W, the attraction plate 251 moves to a site directly above the temporary placement table 22 upon pivotal movement of the arm portion 250 constituting the first transport means 25, and the attraction plate 251 lowers together with the arm portion 250 to attract the back W2 of the wafer W. The attraction plate 251 moves upward to lift the wafer W together with the protective member P, and positions the wafer W directly above the chuck table 24a in accordance with the pivotal movement of the arm portion 250. Then, the attraction plate 251 is lowered to place the wafer W on the chuck table 24a. When the attraction by the attraction plate 251 is released, the wafer W is held on the chuck table 24a.

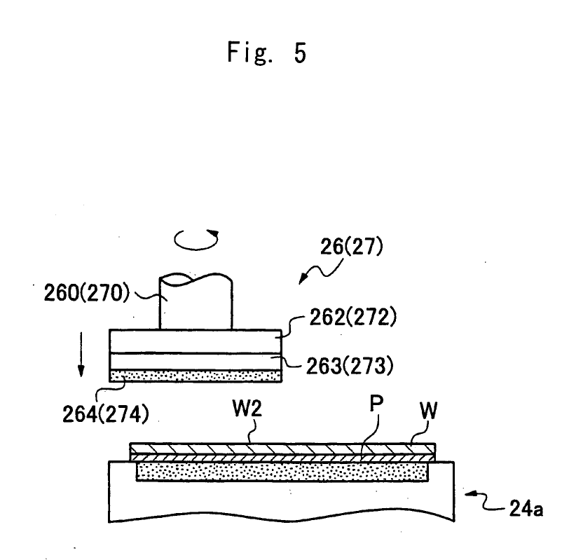

When the wafer W is sucked and held by the chuck table 24a, the turntable 23 is rotated counterclockwise through a predetermined angle (90 degrees in the illustrated embodiment), whereby the wafer W is positioned directly below the first grinding portion 26. As shown in FIG. 5, as the grinding wheel 263 rotates in accordance with the rotation of the spindle 260, the first grinding portion 26 lowers, and the rotating grindstone 264 contacts the back W2 of the wafer W to grind the back W2 roughly.

After completion of the rough grinding, the turntable 23 rotates 90 degrees to bring the wafer W to a position directly below the second grinding portion 27. As shown in FIG. 5, as the grinding wheel 273 rotates in accordance with the rotation of the spindle 270, the second grinding portion 27 lowers, and the rotating grindstone 274 contacts the back W2 of the wafer W to perform finish grinding of the back W2, bringing the wafer W to a predetermined thickness. Since the first grinding portion 26 and the second grinding portion 27 have the same structure, FIG. 5 shows both of the rough grinding by the first grinding portion 26 and the finish grinding by the second grinding portion 27.

After completion of the finish grinding, the turntable 23 rotates 90 degrees to bring the wafer W to a position in the vicinity of the cleaning means 28. Upon pivotal movement of the arm portion 290 constituting the second transport means 29, the attraction plate 291 moves to a site directly above the wafer W subjected to finish grinding, and the attraction plate 291 lowers together with the arm portion 290 to attract the back W2 of the wafer W. The attraction plate 291 moves upward to lift the wafer W together with the protective member P, and positions the wafer W directly above the spinner table 280 constituting the cleaning means 28 in accordance with the pivotal movement of the arm portion 290. Then, the attraction plate 291 is lowered to place the wafer W on the spinner table 280. When the attraction by the attraction plate 291 is released, the wafer W is held on the spinner table 280.

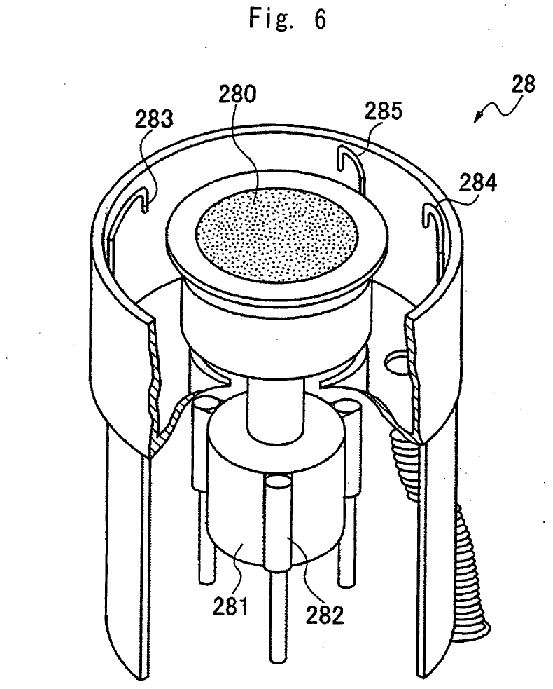

In the cleaning means 28, as shown in FIG. 6, the spinner table 280 is driven by a motor 281 to be rotatable. The motor 281 can be raised and lowered by an air piston 282, and the spinner table 280 can also be raised and lowered accordingly. A cleaning water nozzle 283 for ejecting cleaning water, an air nozzle 284 for ejecting air, and an undercoating liquid jet nozzle 285 for ejecting an undercoating liquid (to be described later) are provided around the spinner table 280.

When the wafer W is to be placed on the spinner table 280 by the second transport means 29, the spinner table 280 is raised by the air piston 282. When the wafer W is held on the spinner table 280, the spinner table 280 is lowered, whereafter the spinner table 280 is driven by the motor 281 to rotate at a high speed. Cleaning water is ejected from the cleaning water nozzle 283 to clean the back W2 of the wafer W. After cleaning, air is ejected from the air nozzle 284, with the spinner table 280 rotating at a high speed, to remove cleaning water. To promote the adhesion of the liquid resist to the back W2 in the resist film coating means 3 and improve the adhesion state, the undercoating liquid may be ejected from the undercoating liquid jet nozzle 285 and coated on the entire surface of the back W2.

When the back W2 of the wafer W is ground, cleaned and, if desired, coated with the undercoating liquid in the above-mentioned manner, the wafer W is carried out from the spinner table 280 by the transport device 4, and transported to the resist film coating means 3. The holding plate 43 constituting the transport device 4 advances into the cleaning means 28, and holds the cleaned wafer W together with the protective member P. In this state, the transport device 4 carries out the wafer W and places it on the holding table 31a. When attraction by the holding plate 43 is released, the wafer W is held on the holding table 31a, with the back W2 being pointed upward.

Then, the turntable 30 rotates clockwise, whereby the holding table 31a holding the wafer W is positioned directly below the infrared imaging portion 32. The infrared camera 321 passes infrared radiation through the wafer W to pick up an image of the face W1, and stores this image in the memory. In the stored image, the streets S (see FIG. 3) formed on the face W1 can be recognized by X-Y coordinates.

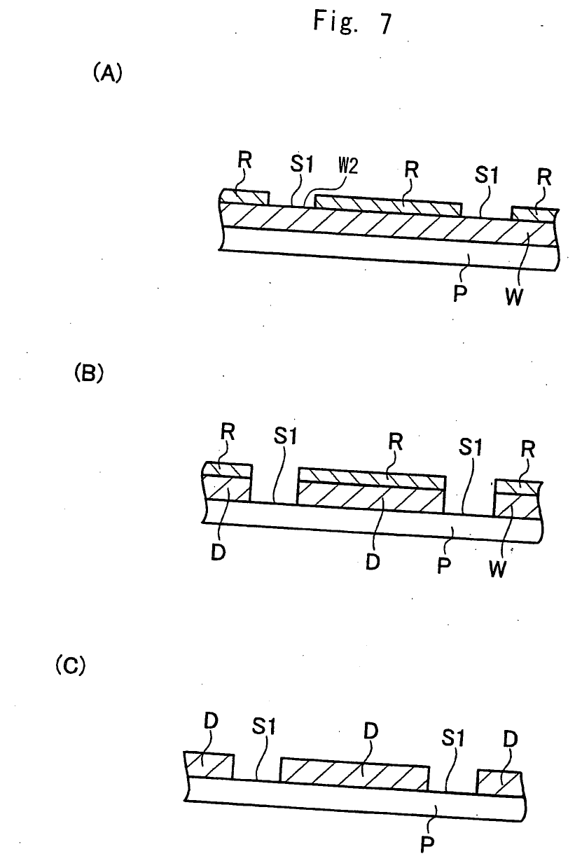

Then, the turntable 30 is rotated clockwise through 90 degrees to position the wafer W directly below the resist jetting portion 34. In the resist jetting portion 34, the liquid resist is spouted from the resist nozzle 341 based on the stored image of the face W1 of the wafer W, with the moving portion 340 being moved in the Y-axis direction; and with the resist nozzle 341 being moved in the X-axis direction. As shown in FIG. 7(A), a resist film R is formed in regions of the back W2 of the wafer W which are other than street-corresponding regions S1. In spouting the liquid resist, the same coordinate system as that for the image stored by the infrared imaging portion 32 is used to control the resist nozzle 341 so as to move avoiding the street-corresponding regions S1. Under this control, the liquid resist is targeted only at the regions other than the street-corresponding regions S1, and the liquid resist is not supplied to the street-corresponding regions S1. The width of the street-corresponding region S1 may be nearly the same as the width of the street S shown in FIG. 3, or may be smaller than the width of the street S. As noted here, the resist can be ejected from the resist nozzle 341, with the street-corresponding regions S1 being evaded, and only the street-corresponding regions S1 can be exposed. Thus, there is no need for the operation of coating the resist film on the entire back, and then cutting the resist film above the street-corresponding regions, or exposing such resist film to light for etching. Hence, the procedure is efficient, and an light exposure device or the like for etching is unnecessary.

The wafer W spouting the liquid resist applied thereon is positioned directly below the heating portion 36, since the turntable 30 rotates clockwise through 90 degrees. The liquid resist is heated by the heating portion 36, and solidified thereby, so that the resist film R is coated in place. The wafer W thus coated with the resist film R is returned to the original position (the position where the wafer W was placed on the holding table 31a), since the turntable 30 is rotated clockwise through 90 degrees. The wafer W is held by the holding plate 43 constituting the transport device 4, and the moving portion 41 is moved in the +X-direction, whereby the wafer W is transported to the plasma etching means 5. The wafers are carried out, one after another, to the holding tables 31a, 31b, 31c, 31d, and the backs of all wafers are coated with the resist film, with the street-corresponding regions being evaded. The so coated wafers are transported to the plasma etching means 5 by the transport device 4.

In the plasma etching means 5, as shown in FIG. 2, when the wafer W having the resist film R coated thereon is transported by the transport device 4, the shutter 67 is lowered to open the opening portion 66. The holding plate 43 constituting the transport device 4, while holding the wafer W, advances into the chamber 53 through the opening portion 66, whereupon the wafer W is held on the suction portion 53a, with the resist film R-coated back W2 facing upward and being exposed. After the holding plate 43 is retreated to outside the chamber 53, the shutter 67 is returned to the original position to close the opening portion 66, and the interior of the chamber 53 is evacuated.

Then, the etching gas spouting means 54 is lowered and, in this state, a fluorine-based stable gas is supplied, as an etching gas, from the gas supply portion 51 to the gas flow-through hole 57. When the etching gas is spouted from the spouting portion 57a at the lower surface of the etching gas spouting means 54, and a high frequency voltage is applied between the etching gas spouting means 54 and the chuck table 55 from the high frequency power source 72, the etching gas is plasmatized. In the back W2 of the wafer W, only the street-corresponding regions S1, which have not been coated with the resist film R, are etched by the etching effect of the plasma. When etching takes place by the amount corresponding to the thickness of the wafer W, the wafer W is separated into individual devices as shown in FIG. 7(B).

After the wafer W is separated into the individual devices, the resist film R coated on the back W2 of the wafer W is removed as shown in FIG. 7(C). The plasma etching means 5 can be used for the removal of the resist film R. In removing the resist film R by use of the plasma etching means 5, the fluorine-based stable gas used in the etching of the street-corresponding regions S1 is discharged through the exhaust port 71 to the gas discharge portion 70 to render the interior of the chamber 53 free from the fluorine-based stable gas. Then, an O₂ gas is supplied from the gas supply portion 51 to the gas flow-through hole 57, and the O₂ gas is spouted from the spouting portion 57a at the lower surface of the etching gas spouting means 54. When a high frequency voltage is applied between the etching gas spouting means 54 and the chuck table 55 by the high frequency power source 72, the O₂ gas is plasmatized. As a result, the resist film R is oxidized, ashed and removed, with the result that only the individual devices D remain while being affixed to the protective member P, as shown in FIG. 7(D).

When the wafer W is divided into the individual devices D, and the resist film R is removed, the shutter 67 is lowered to open the opening portion 66. The holding plate 43 of the transport device 4 is admitted into the chamber 53 to allow the holding plate 43 to hold the wafer W affixed to the protective member P and separated into the devices D. In this state, the holding plate 43 is retreated out of the chamber 53 to carry out the wafer W and accommodate the wafer W into a divided wafer cassette 73 placed outside the plasma etching means 5.

As described above, in the wafer machining apparatus 1 shown in FIG. 1, the back of the wafer can be ground in the grinding means 2 to bring the wafer to a predetermined thickness, the resist film can be coated in the regions of the back of the wafer, which are other than the street-corresponding regions, in the resist film coating means 3, and the street-corresponding regions can be etched in the plasma etching means to divide the wafer into individual devices. Since a series of operations can be performed by the single apparatus, productivity is high and, since the wafer is not cut, the quality of the wafer does not deteriorate.

What we claim is:

1. A wafer machining apparatus for dividing a wafer, in which a plurality of devices are partitioned by streets formed on a face of the wafer, into individual devices, comprising:
grinding means for grinding a back of the wafer having a protective member affixed to the face of the wafer to form the wafer in a predetermined thickness;
resist film coating means for passing a radiation from a back side to a face side of the wafer to recognize the streets, and coating a resist film onto regions of the back of the wafer which are other than street-corresponding regions corresponding to the streets; and
plasma etching means for plasmatizing a fluorine-based stable gas, and supplying the plasmatized gas to the back side of the wafer to etch away the street-corresponding regions in a range from the back to the face of the wafer, thereby dividing the wafer into individual devices, and
wherein the grinding means at least comprises a chuck table for sucking and holding the wafer, a grinding portion for grinding the back of the wafer held on the chuck table, and a cleaning portion for cleaning the ground wafer, and
the resist film coating means at least comprises a holding table for holding the wafer, an infrared imaging portion for imaging the wafer held on the holding table from the back side to recognize the streets formed on the face side, a resist jetting portion for jetting a liquid resist toward the regions of the back of the wafer which are other than the street-corresponding regions, and a heating portion for heating the jetted liquid resist to solidify the jetted liquid resist.

2. The wafer machining apparatus according to claim 1, wherein the cleaning portion is equipped with an undercoating liquid jet nozzle for jetting an undercoating liquid for rendering a state of adhesion of the liquid resist to the back of the wafer satisfactory.

3. The wafer machining apparatus according to claim 1, wherein the fluorine-based stable gas is one of SF₆, CF₄, C₂F₆, C₂F₄ and CHF₃.

4. The wafer machining apparatus according to claim 1, wherein the plasma etching means has a function of plasmatizing oxygen, and supplying the plasmatized oxygen to the back side of the wafer divided into the devices to ash and remove the resist film coated on the backs of the devices.
